(19) United States
(12) Patent Application Publication
(10) Pub. No.: US 2015/0115461 A1
(43) Pub. Date: Apr. 30, 2015

(54) SEMICONDUCTOR STRUCTURE AND METHOD FOR FORMING THE SAME

(71) Applicant: UNITED MICROELECTRONICS CORP., Hsinchu (TW)

(72) Inventors: Chih-Chou Yu, Hsinchu City (TW); Hsueh-Chun Hsiao, Hsinchu County (TW); Tzu-Yun Chang, Hsinchu County (TW)

(73) Assignee: UNITED MICROELECTRONICS CORP., Hsinchu (TW)

(21) Appl. No.: 14/066,845

(22) Filed: Oct. 30, 2013

(51) Int. Cl. H01L 23/538; H01L 21/768

(52) U.S. Cl. CPC H01L 23/5384; H01L 21/76898
USPC 257/774; 438/107

(57) ABSTRACT

A semiconductor structure and a method for forming the same are provided. The method includes following steps. A first wafer is provided, which includes a first region, a second region, and a first semiconductor device disposed in the first region. No semiconductor device is disposed in the second region. A second wafer is provided, which includes a third region, a fourth region and a second semiconductor device disposed in the third region. No semiconductor device is disposed in the fourth region. The first region of the first wafer is overlapped with the fourth region of the second wafer. The second region of the first wafer is overlapped with the third region of the second wafer. A first conductive through via is formed to pass through the fourth region of the second wafer and the first region of the first wafer to electrically connect to the first semiconductor device.

### BACKGROUND

1. Technical Field

The disclosure relates to a semiconductor structure and a method for forming the same, and more particularly to a semiconductor structure having two wafers and a method for forming the same.

2. Description of the Related Art

Along with the advance in semiconductor technology, semiconductor devices are kept being miniaturized, such that electronic products possess more and more functions when the size remains unchanged or become even smaller. Integrating various manufacturing processes is needed for the semiconductor devices in different regions. However, the complex processes increases manufacturing cost and production cycle time.

### SUMMARY

According to one embodiment, a method for forming a semiconductor structure is provided, comprising following steps. A first wafer is provided. The first wafer comprises a first semiconductor device, a first region and a second region. The first semiconductor device is disposed in the first region. No semiconductor device is disposed in the second region. A second wafer is provided. The second wafer comprises a second semiconductor device, a third region and a fourth region. The second semiconductor device is disposed in the third region. No semiconductor device is disposed in the fourth region. The first region of the first wafer is overlapped with the fourth region of the second wafer. The second region of the first wafer is overlapped with the third region of the second wafer. A first conductive through via is formed to pass through the fourth region of the second wafer and the first region of the first wafer to electrically connect to the first semiconductor device.

According to another embodiment, a semiconductor structure is provided. The semiconductor structure comprises a first wafer, a second wafer and a first conductive through via. The first wafer comprises a first semiconductor device, a first region and a second region. The first semiconductor device is disposed in the first region. No semiconductor device is disposed in the second region. A second wafer comprises a second semiconductor device, a third region and a fourth region. The second semiconductor device is disposed in the third region. No semiconductor device is disposed in the fourth region. The second wafer is bonded to the first wafer. The first region of the first wafer is overlapped with the fourth region of the second wafer. The second region of the first wafer is overlapped with the third region of the second wafer. The first conductive through via passes through the fourth region of the second wafer and the first region of the first wafer to electrically connect to the first semiconductor device.

### BRIEF DESCRIPTION OF THE DRAWINGS

FIG. 1A to FIG. 1D illustrate a method for forming a semiconductor structure.

### DETAILED DESCRIPTION

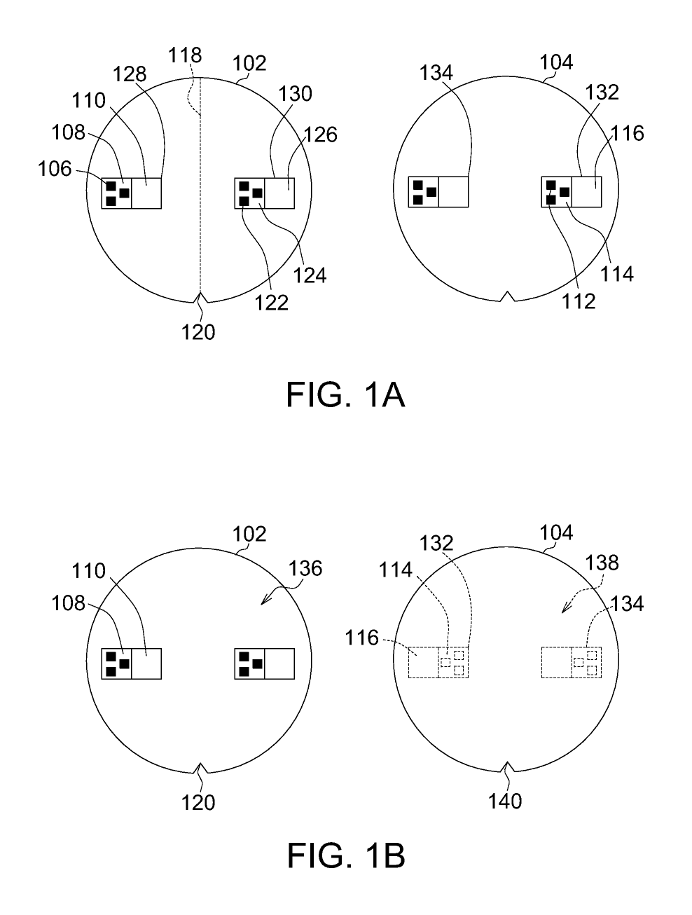

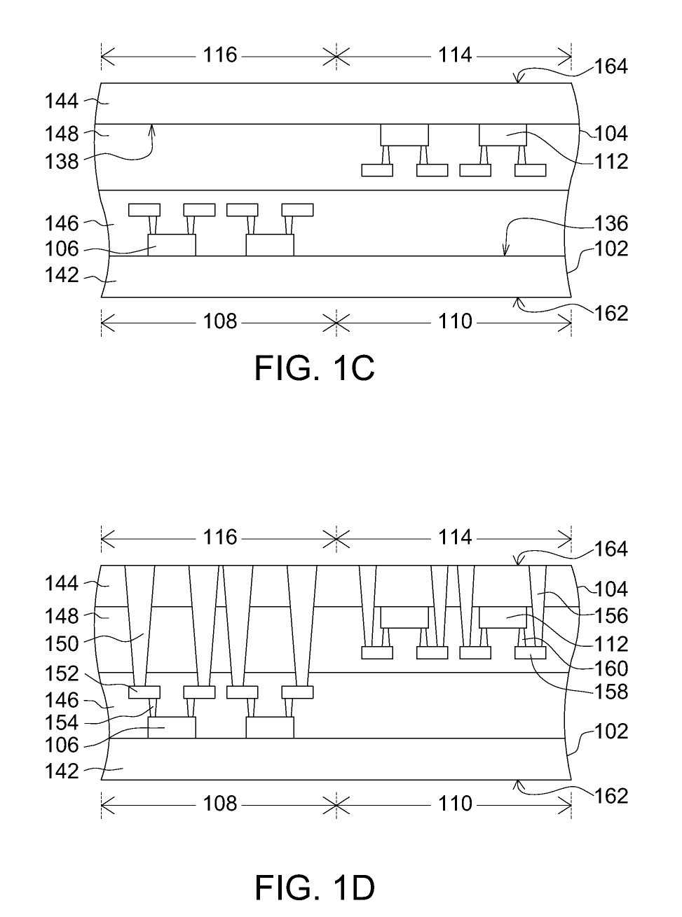

FIG. 1A to FIG. 1D illustrate a method for forming a semiconductor structure.

FIG. 1A shows top views of a first wafer 102 and a second wafer 104. The first wafer 102 comprises a first semiconductor device 106 disposed in a first region 108. There is no semiconductor device disposed in the second region 110 adjacent to the first region 108 of the first wafer 102. The second wafer 104 comprises a second semiconductor device 112 in a third region 114. There is no semiconductor device disposed in a fourth region 116 adjacent to the third region 114 of the second wafer 104. In one embodiment, the third region 114 of the second wafer 104 is corresponded to a region of the first wafer 102 mirrored in location (or symmetrical location) with the second region 110 of the first wafer 102 according to a (fictitious) center line 118 passing a notch 120 of the first wafer 102. In addition, the fourth region 116 of the second wafer 104 is corresponded to a region of the first wafer 102 mirrored in location with the first region 108 of the first wafer 102 according to the center line 118.

The first wafer 102 may comprise a third semiconductor device 122 in a fifth region 124. There is no semiconductor device disposed in a sixth region 126 adjacent to the fifth region 124 of the first wafer 102. The first region 108 and the second region 110 of the first wafer 102 may form a first pattern structure 128, and the fifth region 124 and the sixth region 126 of the first wafer 102 may form a second pattern structure 130. In one embodiment, the first pattern structure 128 is the same as the second pattern structure 130, in other words, areas of the first region 108 and the fifth region 124, areas of the second region 110 and the sixth region 126, and designs for the first semiconductor device 106 in the first region 108 and the third semiconductor device 122 in the fifth region 124, such as device types, arrangements, etc., are the same. In one embodiment, the first pattern structure 128 and the second pattern structure 130 are disposed in mirror (or symmetrical) locations according to the center line 118. For example, the first region 108 and the sixth region 126 are disposed in mirror locations according to the center line 118. The second region 110 and the fifth region 124 are disposed in mirror locations according to the center line 118. The concept may be applied to a third pattern structure 132 and a fourth pattern structure 134 of the second wafer 104, but not limited thereto. In one embodiment, the first pattern structure 128 and the second pattern structure 130 are formed by the same process and mask applied for the third pattern structure 132 and the fourth pattern structure 134 of the second wafer 104, but not limited thereto.

FIG. 1B shows the top view of the first wafer 102, and a bottom view of the second wafer 104 after being reversed. Since, as observed from the top view of FIG. 1A, the first region 108 and the fourth region 116 are disposed in corresponding mirror locations for a wafer, referring to FIG. 1B, after the first wafer 102 and the second wafer 104 are substantially wholly overlapped with facing active surfaces 136 and 138 to each other and aligning notches 120 and 140 of the first wafer 102 and the second wafer 104, the first region 108 is overlapped by the fourth region 116. Similarly, the second region 110 of the first wafer 102 is overlapped by the third region 114 of the second wafer 104. The concept may be applied to the third pattern structure 132 and the fourth pattern structure 134.

FIG. 1C, for the sake of brevity, only shows a cross-section view of the first region 108 and the second region 110 of the first wafer 102 and the third region 114 and the fourth region 116 of the second wafer 104 after being bonded together with active surfaces 136 and 138 facing to each other according to one embodiment. The first wafer 102 and the second wafer 104 comprise wafer substrates 142 and 144 and dielectric layers 146 and 148 covering the first semiconductor device 106 and the second semiconductor device 112 formed on the wafer substrates 142 and 144, respectively.

Referring to FIG. 1D, a first conductive through via 150 is formed to pass through the wafer substrate 144 and the dielectric layer 148 in the fourth region 116 of the second wafer 104 and the dielectric layer 146 in the first region 108 of the first wafer 102 to electrically connect to a conductive layer 152 so as to electrically connect to the first semiconductor device 106 through a conductive plug 154. A second conductive through via 156 is formed to pass through the wafer substrate 144 and the dielectric layer 148 in the third region 114 of the second wafer 104 to electrically connect a conductive layer 158 so as to electrically connect to the second semiconductor device 112 through a conductive plug 160.

For example, a process for forming the first conductive through via 150 and the second conductive through via 156 may comprise the following steps. A patterned photoresist (not shown) is formed on one of back surfaces 162 and 164 of the wafer substrates 142 and 144 shown in FIG. 1C. A portion of the structure exposed by an opening of the patterned photoresist is removed to form through vias. The patterned photoresist is removed. Then, the through vias are filled with a conductive material to form the first conductive through via 150 and the second conductive through via 156 as shown in FIG. 1D. In embodiments, the through vias for the first conductive through via 150 and the second conductive through via 156 are formed simultaneously by using the same patterned photoresist as an etching mask. In other words, the first conductive through via 150 and the second conductive through via 156 can be formed simultaneously by using the same mask.

In one embodiment, the method described above is applied for through silicon via (TSV) testkey design and the first semiconductor device 106 and the second semiconductor device 112 comprise a device under test. According to embodiments, the first conductive through via 150 and the second conductive through via 156 for electrically connecting to the different first and second wafers 102 and 104 can be formed simultaneously by using only one mask, and therefore learning cycle is fast and cost for test is low.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for forming a semiconductor structure, comprising:
providing a first wafer comprising a first semiconductor device, a first region and a second region, wherein the first semiconductor device is disposed in the first region, no semiconductor device is disposed in the second region;
providing a second wafer comprising a second semiconductor device, a third region and a fourth region, wherein the second semiconductor device is disposed in the third region, no semiconductor device is disposed in the fourth region;
overlapping the first region of the first wafer with the fourth region of the second wafer, and the second region of the first wafer with the third region of the second wafer; and
forming a first conductive through via passing through the fourth region of the second wafer and the first region of the first wafer to electrically connect to the first semiconductor device.

2. The method for forming the semiconductor structure according to claim 1, wherein each of the first wafer and the second wafer comprises a wafer substrate and a dielectric layer formed on the wafer substrate, the first conductive through via passes through the wafer substrate and the dielectric layer of the second wafer.

3. The method for forming the semiconductor structure according to claim 2, wherein the first semiconductor device is disposed on the wafer substrate and covered by the dielectric layer of the first wafer, the first conductive through via passes through the wafer substrate and the dielectric layer of the second wafer and the dielectric layer of the first wafer to electrically connect to the first semiconductor device.

4. The method for forming the semiconductor structure according to claim 1, wherein the first semiconductor device and the second semiconductor device comprise a device under test.

5. The method for forming the semiconductor structure according to claim 1, comprising facing an active surface of the first wafer to an active surface of the second wafer.

6. The method for forming the semiconductor structure according to claim 1, comprising bonding the first wafer and the second wafer.

7. The method for forming the semiconductor structure according to claim 1, comprising aligning notches of the first wafer and the second wafer.

8. The method for forming the semiconductor structure according to claim 1, wherein the first region of the first wafer is corresponded to a region of the second wafer mirrored in location with the fourth region of the second wafer according to a center line passing a notch of the second wafer.

9. The method for forming the semiconductor structure according to claim 1, wherein the first wafer further comprises a third semiconductor device, a fifth region and a sixth region, the third semiconductor device is disposed in the fifth region, no semiconductor device is disposed in the sixth region, the first region and the second region of the first wafer form a first pattern structure, the fifth region and the sixth region of the first wafer form a second pattern structure.

10. The method for forming the semiconductor structure according to claim 9, wherein the first region and the sixth region are disposed in mirror locations, the second region and the fifth region are disposed in mirror locations according to a center line passing a notch of the first wafer.

11. The method for forming the semiconductor structure according to claim 9, wherein the first pattern structure is the same as the second pattern structure.

12. The method for forming the semiconductor structure according to claim 9, wherein the first pattern structure and the second pattern structure are disposed in mirror locations according to a center line passing a notch of the first wafer.

13. The method for forming the semiconductor structure according to claim 1, further comprising forming a second conductive through via passing through the third region of the second wafer to electrically connect to the second semiconductor device.

14. The method for forming the semiconductor structure according to claim 13, wherein the first conductive through via and the second conductive through via are formed by using the same mask.

15. The method for forming the semiconductor structure according to claim 13, wherein each of the first conductive through via and the second conductive through via is a single conductive through via.

16. The method for forming the semiconductor structure according to claim 13, wherein the second wafer comprises a wafer substrate and a dielectric layer formed on the wafer substrate, the second conductive through via passes through the wafer substrate and the dielectric layer of the second wafer to electrically connect to the second semiconductor device.

17. A semiconductor structure, comprising:
a first wafer comprising a first semiconductor device, a first region and a second region, wherein the first semiconductor device is disposed in the first region, no semiconductor device is disposed in the second region;
a second wafer comprising a second semiconductor device, a third region and a fourth region, wherein the second semiconductor device is disposed in the third region, no semiconductor device is disposed in the fourth region, the second wafer is bonded to the first wafer, the first region of the first wafer is overlapped with the fourth region of the second wafer, and the second region of the first wafer is overlapped with the third region of the second wafer; and
a first conductive through via passing through the fourth region of the second wafer and the first region of the first wafer to electrically connect to the first semiconductor device.

18. The semiconductor structure according to claim 17, wherein each of the first wafer and the second wafer comprises a wafer substrate and a dielectric layer on the wafer substrate, the first conductive through via passes through the wafer substrate and the dielectric layer of the second wafer, and the dielectric layer of the first wafer to electrically connect to the first semiconductor device.

19. The semiconductor structure according to claim 17, further comprising a second conductive through via, wherein the second wafer comprises a wafer substrate and a dielectric layer on the wafer substrate, the second conductive through via passes through the wafer substrate and the dielectric layer of the second wafer to electrically connect to the second semiconductor device in the third region.

20. The semiconductor structure according to claim 19, wherein each of the first conductive through via and the second conductive through via is a single conductive through via.
